(19) United States
(12) Patent Application Publication
(10) Pub. No.: US 2015/0214339 A1
(43) Pub. Date: Jul. 30, 2015

(54) TECHNIQUES FOR ION IMPLANTATION OF NARROW SEMICONDUCTOR STRUCTURES

(71) Applicant: Varian Semiconductor Equipment Associates, Inc., Gloucester, MA (US)

(72) Inventors: ANDREW M. WAITE, Beverly, MA (US); KALIPATNAM VIVEK RAO, Grafton, MA (US)

(73) Assignee: Varian Semiconductor Equipment Associates, Inc., Gloucester, MA (US)

(21) Appl. No.: 14/163,739

(22) Filed: Jan. 24, 2014

(51) Int. Cl. H01L 29/66; H01L 29/167; H01L 21/324; H01L 21/265

(52) U.S. Cl. CPC H01L 29/66803; H01L 21/26513; H01L 29/167; H01L 21/324

(57) ABSTRACT

A method to process a semiconductor device includes performing a first ion implant comprising first ions into a thin crystalline semiconductor structure, the first ion dose amorphizing a first region of the thin crystalline semiconductor structure; performing a second ion implant comprising dopant ions of a dopant species into at least the first region of the thin crystalline semiconductor structure; and performing at least one anneal of the semiconductor device after the first implant, wherein after the first and second implant and the at least one anneal, the thin crystalline semiconductor structure forms a mono-crystalline region without defects.

### FIELD

The present embodiments relate to processing of field effect transistors, and more particularly to ion implantation field effect transistors.

### BACKGROUND

As semiconductor devices scale to smaller dimensions, non-planar transistors are increasingly attractive as alternatives to planar transistors due to the limits on scalability imposed by planar transistor geometry. For example, so-called fin field effect transistors (finFET) have been deployed in complementary metal oxide semiconductor (CMOS) technology for the 22 nm device generation. A finFET is a type of three dimensional (3-D) transistor in which a narrow strip of semiconductor material (fin) that extends vertically from a main substrate surface is used to form source/drain (S/D) and channel regions of the transistor. A transistor gate is then deposited to wrap around opposite sides of the fin thereby forming a gate structure that bounds multiple sides of the channel.

During processing to form a conventional finFET after etching the semiconductor substrate to define a fin structure, various implantation steps into the fin structure are performed to form source/drain (S/D) regions, source/drain extension (SDE) regions, threshold voltage adjustment implants, and so forth. Certain implants, such as S/D implants and SDE implants in particular entail a relatively high dose of implanting species required to achieve the required level of doping in the fin structure, such as 1 E15/cm². In the case of arsenic (As) implants due to the large atomic mass of the implanting species, it is often found that the fin structure becomes sufficiently damaged during implantation as to render the fin structure polycrystalline after post-implantation annealing.

Although implantation at elevated temperatures, for example, above 300° C., may reduce or eliminate amorphized material during an As implantation, crystalline defects are found after post-implantation annealing, especially when the implant temperature exceeds 300° C. These defects may be associated with decreased device performance. Accordingly, merely increasing substrate temperature to avoid amorphization of a crystalline semiconductor fin during implantation may not lead to fin structures that possess desired electrical properties. It is with respect to these and other considerations that the present improvements are needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a method to process a semiconductor device includes performing a first ion implant comprising first ions into a thin crystalline semiconductor structure, the first ion dose amorphizing a first region of the thin crystalline semiconductor structure; performing a second ion implant comprising dopant ions of a dopant species into at least the first region of the thin crystalline semiconductor structure; and performing at least one anneal of the semiconductor device after the first implant, wherein after the first and second implant and the at least one anneal, the thin crystalline semiconductor structure forms a mono-crystalline region without defects.

In a further embodiment, a method of forming a fin type field effect transistor (finFET) includes providing a fin structure extending perpendicularly to the substrate surface, the fin structure comprising a monocrystalline semiconductor having a fin thickness of less than 50 nm; performing a first ion implant comprising first ions into the fin structure, the first ion dose amorphizing a first region of the thin crystalline semiconductor structure; performing a second ion implant comprising dopant ions of a dopant species into at least the first region of the fin structure at an implantation temperature above 300° C.; and performing at least one anneal of the semiconductor device after the first implant, wherein after the first and second implant and the at least one anneal, the fin structure forms a mono-crystalline region without defects.

### BRIEF DESCRIPTION OF THE DRAWINGS

FIGS. 1A, 1B, and 1C show an isometric view, top plan view, and side view of an exemplary geometry of ion implantation of a device consistent with various embodiments;

FIG. 2A-2C depict various operation involved in an implantation process consistent with embodiments of the disclosure;

FIGS. 3A-3C depict various operation involved in another implantation process consistent with other embodiments of the disclosure;

FIGS. 4A-4D depict various operation involved in a further implantation process consistent with additional embodiments of the disclosure;

FIGS. 5A-5D depict various operation involved in still another implantation process consistent with still other embodiments of the disclosure.

### DETAILED DESCRIPTION

The present embodiments will now be described more fully hereinafter with reference to the accompanying drawings, in which some embodiments are shown. The subject matter of the present disclosure, however, may be embodied in many different forms and should not be construed as limited to the embodiments set forth herein. Rather, these embodiments are provided so that this disclosure will be thorough and complete, and will fully convey the scope of the subject matter to those skilled in the art. In the drawings, like numbers refer to like elements throughout.

To address some of the deficiencies in the aforementioned implantation processes, embodiments are described herein that provide improved techniques for forming devices having thin or narrow semiconductor layers or structures, such as finFET devices. The present embodiments in particular provide novel ion implantation operations that facilitate doping of thin mono-crystalline semiconductor regions without creating deleterious defects.

In various embodiment multiple implantation operations are performed into a thin semiconductor structure in which at least one ion implantation process (referred to herein as an “implant”) generates an amorphous region. One or more additional implants are performed, which may take place at elevated temperature above ambient temperature (25° C.). The multiple implants avoid problems resulting from single implant processes as discussed above.

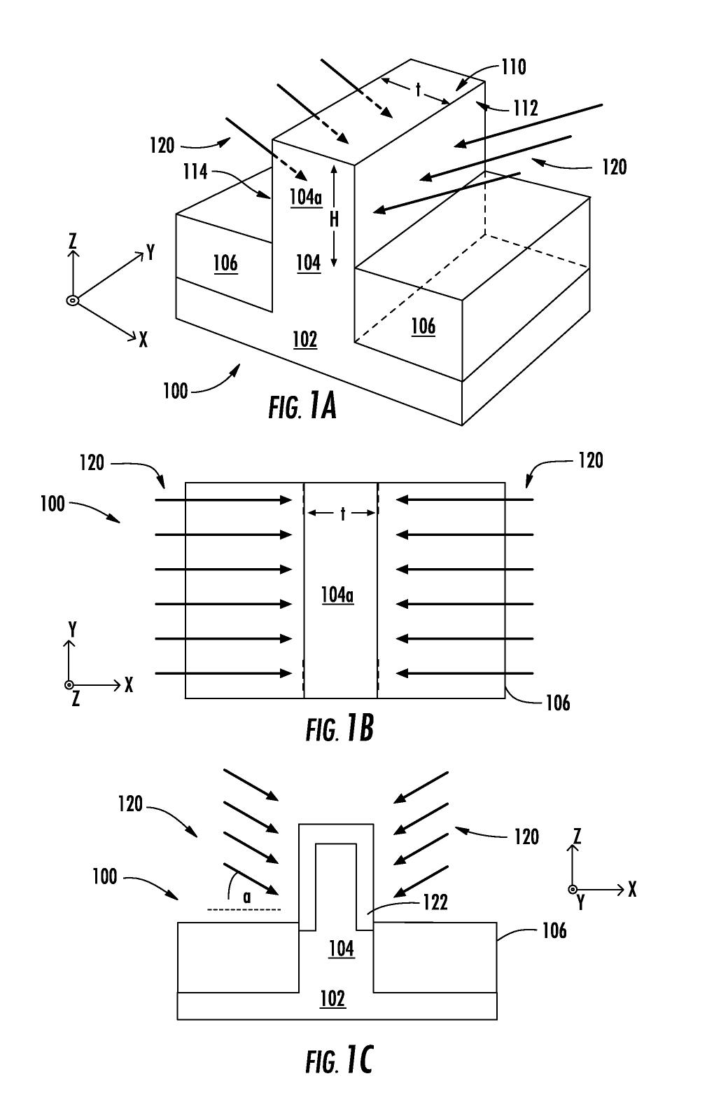

For purposes of illustration FIGS. 1A-1C depict different views that illustrate the geometry of an ion implant process of a finFET device consistent with various embodiments. The finFET device 100 includes a base portion 102 that is a mono-crystalline semiconductor material. The base portion 102 may extend in a substrate plane that lies parallel to the X-Y plane of the Cartesian coordinate system shown. A fin structure 104 may be formed by conventional methods from the base portion 102 as a unitary structure that extends in a direction perpendicularly (along the Z-axis of the Cartesian coordinate system shown) to the plane of the substrate (X-Y plane). The fin structure 104 is partially flanked by oxide layer 106, which may be formed according to known techniques. The oxide layer 106 is recessed so that the fin structure 104 extends above the oxide layer 106 to a height H to expose a side 114, a side 112 opposite to the side 114, and a top 110. The fin portion has a thickness t, which in various embodiments is 50 nm or less. In order to properly dope the fin portion 104 without creating unwanted crystalline defects multiple implant operations may be performed, which are illustrated by the ions 120. In different embodiments as detailed below, the ions 120 may be directed at least at one of side of a fin, such as one of sides 112, 114, as well as at the top 110 of the fin structure 104. An angle of angles of incidence a of the ions 120 may be chosen to produce the desired implant depth and dopant concentration profile as well as damage profile. In some examples, the ions 120 may form an angle a with respect to a perpendicular to a substrate plane (Z-direction) of between 0 and 45 degrees. The embodiments are not limited in this context.

In accordance with various embodiments as detailed with respect to the FIGS. to follow, at least one of multiple implants is performed to amorphize at least a region of the fin structure, such as fin structure 104. Additionally, at least additional implant is performed in addition to the implant that produces the amorphous region. In various embodiments, the additional implant may be performed at elevated implant temperature such that, in combination with the amorphizing implant, and after post-implantation annealing, a fin structure is produced that is monocrystalline, free of visible defects and contains active dopants of a desired concentration. As used herein, the term “free of visible defects” may refer to a defect level lower than 1 E7/cm² for defects 3 nm or larger, both of which represent limits observable in present day transmission electron microscopy.

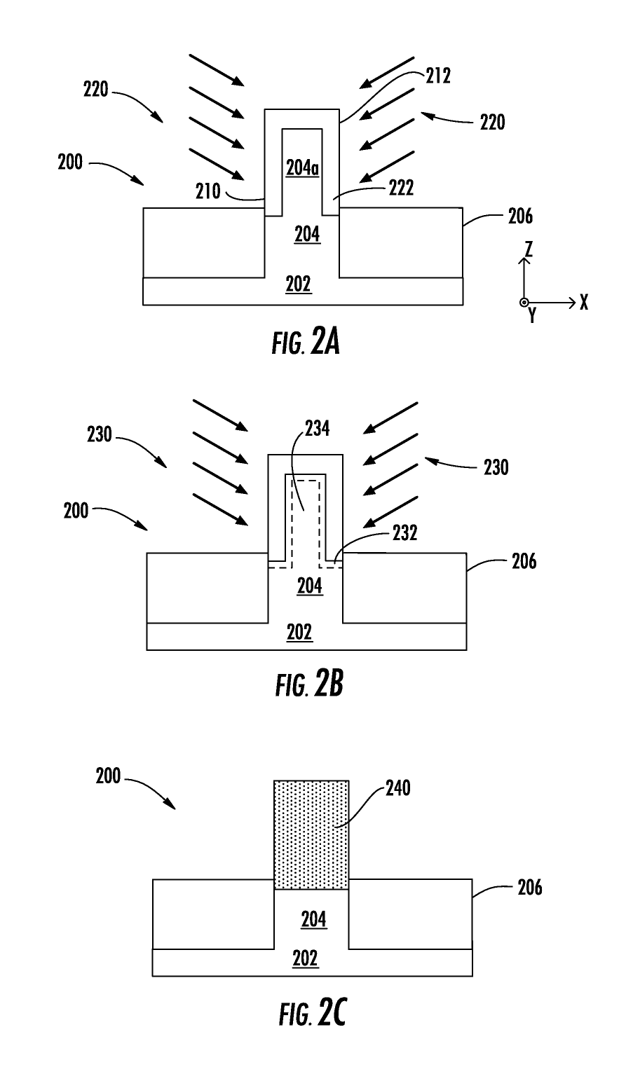

FIGS. 2A-2C depict various operation involved in an implantation process consistent with embodiments of the disclosure. In FIG. 2A there is shown a substrate 200 that includes a semiconductor base 202 that extends in a plane parallel to the X-Y plane from which a fin structure 204 extends vertically along the Z direction. In various embodiments of the disclosure, the fin structure 204 and semiconductor base 202 form an integral monocrystalline semiconductor material such as silicon, silicon:germanium alloy, a compound semiconductor material, or other semiconductor.

In one example, ions 220 are implanted into the substrate 200, and in particular implant into the exposed portion 204A of the fin structure 204. The ions 220 may be generated by any convenient apparatus for directing ions to a substrate. Systems that are suitable for generating ions 220 include conventional beamline implanters whose operation is known, which are used to generate a beam of ions that may be collimated when reaching the substrate 200. In some cases the substrate or beam may be moved with respect to one another, such as by tilting, rotating, translating or performing a combination of movements on the substrate or beam in order to expose a substrate to ions in different locations or along different orientations. In the example of FIG. 2A and in the figures to follow ions may be directed at a non-zero angle with respect to a perpendicular (along the Z-axis) to the substrate plane (X-Y) which results in the ions 220 implanting into sidewalls 210,212. In order to implant ions 220 into both sidewalls 210,212 the substrate 200 may be rotated about an axis parallel to the Z-axis while an ion beam that contains the ions 220 remains stable.

In other embodiments, the ions 220 may be extracted from a plasma chamber proximate the substrate 200. The ions 220 may be extracted through an aperture plate arranged proximate to a plasma chamber according to known apparatus in which ions 220 are extracted over a range of angles. In this manner, the ions 220 may strike the fin structure 204 simultaneously on both sidewalls 210,212. The embodiments are not limited in this context.

In one embodiment, as shown in FIG. 2A an ion implant may be performed by implanting a dose of ions 220 into both sidewalls 210,212. This may also result in implanting a top portion of the fin structure 204. However, in other embodiments, as detailed in FIGS. to follow, an ion implant may comprise merely implanting a single sidewall of a fin structure. In the embodiment of FIG. 2A the substrate 200 may be heated during implantation to a desired temperature, termed the “implant temperature.” In some embodiments, an implant of ions 220 into the exposed portion 204A of the fin structure 204 is conducted at an implant temperature, ion energy, and ion dose that renders a region of the fin structure 204 amorphous. In particular embodiments in which the fin structure 204 is monocrystalline silicon, suitable species for ions 220 include Ge or Xe, to name two examples. Suitable ion energy for ions 220 is 5 keV or less, which is effective to amorphize single crystal (monocrystalline) silicon when ions 220 are Ge or Xe. The amorphized region is shown in FIG. 2A as amorphous layer 222, which extends around the exposed portion 204a of the fin structure 204. The layer 232 may in some examples extend from the outer surface of the fin structure 204 inwardly, thereby constituting a surface layer. Suitable conditions for generating the layer 232 as an amorphous region may be an implant temperature of 300° C. or lower. In examples in which the thickness t (see FIG. 1A) of the fin structure along the X-direction is less than 50 nm the thickness of the layer 232 may be 10 nm or less along the same direction.

Turning now to FIG. 2B, there is shown an operation that is performed subsequent to the implant shown in FIG. 2A. In this example, ions 230 are implanted into the fin structure 204. The ions 230 are dopant ions and are used to introduce dopants into the fin structure 204 to generate a desired concentration of dopants within the semiconductor material than constitutes the fin structure 204. In the example of forming an nFET using the substrate 200, the ions 230 may be an arsenic species such as As, and may be implanted at a dose of 5E14/cm² to 2E15/cm² in different embodiments. In the example of FIG. 2B the implant temperature may be set at 350° C. or higher during the implanting of ions 230. An implant layer, layer 232, is thus formed, which may overlap the amorphous layer 222. In some embodiments, the implant temperature may be 400° C. or higher, such as 450° C. The elevated implant temperature serves to reduce any damage to the exposed portion 204A of the fin structure 204 caused by the implanting ions, ions 230.

Subsequently, a post-implantation anneal process may be performed, which may activate dopants introduced by the ions 230, as well as recrystallize regions of the fin structure 104 that are damaged during implantation shown in FIG. 2A or 2B. Various known anneal processes may be suitable for post-implantation annealing, such as rapid thermal annealing, or “spike” annealing, in which substrate temperature of the substrate 200 is momentarily brought to an elevated temperature for several seconds or less. In some cases, an anneal temperature of the anneal is greater than 800° C. For example, such elevated temperature for annealing a substrate using a spike anneal may range from 800° C. to 1050° C. in some embodiments. However, other annealing processes are suitable and the embodiments are not limited in this context.

Turning now to FIG. 2C, there is shown schematically a resultant structure of the substrate 200 after the ion implants shown in FIGS. 2A and 2B, and after a post-implantation anneal process is performed. The fin structure 204 now comprises a doped region 240 that is monocrystalline and without visible defects. The present inventors have observed, for example when a “pre-amorphizing” implant as represented by FIG. 2A that contains in the range of 1E15/cm² Ge ions is conducted into silicon before a dopant implantation of As at 450° C., as represented by FIG. 2B, the resultant structure after post implant annealing is conducted is a monocrystalline doped silicon material without visible defects. Without limitation, this structure is believed to result from the salutary role played by the presence of the amorphous layer 222 during post implantation annealing, in conjunction with the dopant implantation of ions 230, which is conducted at sufficiently high temperature so as not to create additional damage to the fin structure 104 during implantation of ions 230. When post implant annealing takes place, during the initial stages of annealing, the amorphous layer 222 in particular may act as a sink for defects created during the implantation of ions 230. Instead of propagating as extended loops as observed in conventional high temperature implantation schemes, these defects are sunk by the amorphous layer 222. In later stages of annealing the amorphous layer 222 eventually recrystallizes using interior region 234, which is monocrystalline as a template for growth, resulting in the monocrystalline structure of FIG. 2C without observable defects. Because the implantation of dopant ions, ions 230, takes place at a sufficiently high temperature, the amount of amorphous or damaged region of the fin structure 204 is maintained at a level for which the post implantation annealing is effective to completely recover a monocrystalline microstructure throughout the fin structure 104.

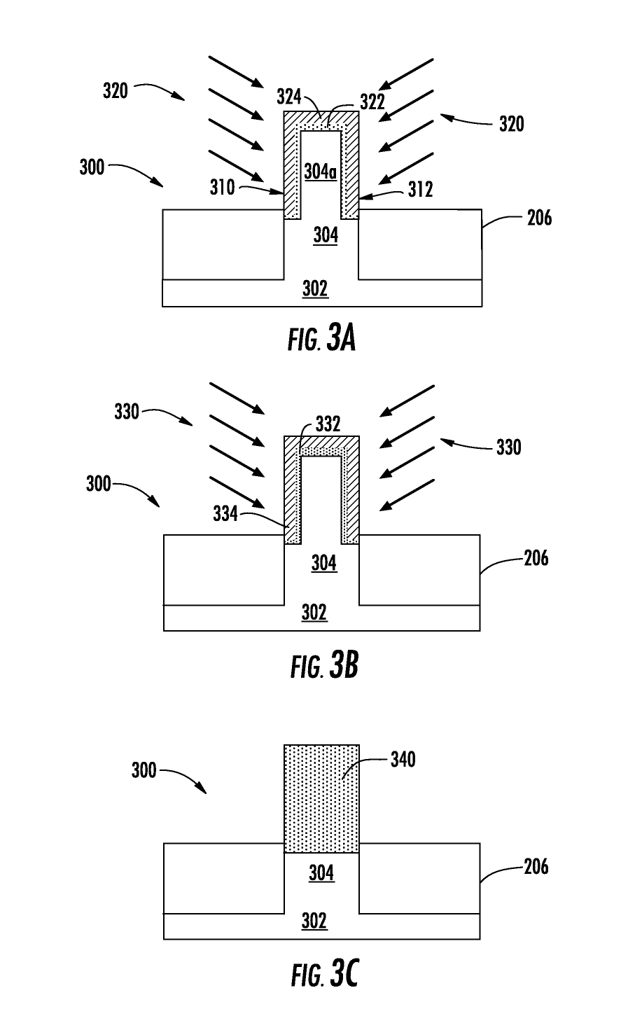

FIGS. 3A-3C depict exemplary operations involved in another implantation process consistent with further embodiments. In FIG. 3A a substrate 300 includes a semiconductor base 302 and fin structure 304, which may be as described above with respect to their counterparts, semiconductor base 202 and fin structure 204. In this embodiment an implant of ions 320 is directed to the exposed portion 304A at an implant temperature above room temperature but below 400° C. The ions 320 may be dopant ions that introduce a first dose of dopant species into the fin structure 304. The implant temperature may be adjusted such that an amorphous layer 324 is generated at least in the exposed portion 304A. In some embodiments an implant of ions 320 may be composed of two separate sub-implants from a beamline apparatus to implant into each sidewall 310,312 separately, while in other embodiments the ions 320 may be directed simultaneously to the sidewalls 310, 312. In addition to the amorphous layer 324, the ions 320 may generate a dopant layer 326 containing the implanted species of ions 320. The dopant layer 326 may overlap the amorphous layer 324 as shown.

In particular embodiments an implant temperature of 250° C.-350° C. may be used to introduce the ions 320 into the fin structure 304. This may serve to limit the thickness of the amorphous layer 324, which may be less than 10 nm in some embodiments.

Turning now to FIG. 3B, there is shown an operation that is performed subsequently to the implant shown in FIG. 3A. In this example, ions 330 are implanted into the fin structure 304. The ions 330 are dopant ions and are used to introduce additional dopants into the fin structure 304 to generate a desired concentration of dopants with the semiconductor material than constitutes the fin structure 304. In various embodiments the ions 320 and ions 330 are the same species such as As. The ions 320, 330 may accordingly be introduced into the fin structure 304 such that the sum of ions 320 and ions 330 that are implanted generates the desired concentration of dopants. The ions 330 may generate a dopant layer 332 in the fin structure 304. The ions 330 may be introduced at an implant temperature of elevated implant temperature of 400° C. or higher, such as 450° C., which serves to reduce any damage to the exposed portion 304A of the fin structure 304 caused by the implanting of ions 330. However, the process of implanting ions 330 may still preserve an amorphous layer 334, which may be similar in extent as amorphous layer 324, may be larger, or may be smaller.

An advantage of performing the implant of ions 330 at elevated temperature of 400° C. or higher is that the total thickness of the amorphous layer 334 may be maintained below a threshold thickness beyond which a monocrystalline fin is not recoverable by annealing. At the same time the implant temperature for ions 330 may be sufficiently low that the pre-existing amorphous material such as amorphous layer 324 is not completely crystallized during the implant of ions 330. This preserves a layer, amorphous layer 334, which may act as a defect sink during post implantation annealing as discussed above.

Turning now to FIG. 3C, there is shown schematically a resultant structure of the substrate 300 after the ion implants shown in FIGS. 3A and 3B, and after a post-implantation anneal process is performed. The fin structure 304 now comprises a doped region 340 that is monocrystalline and without visible defects. This results from the processes discussed above with respect to FIG. 2C.

In various embodiments the fraction of dopant ions apportioned between ions 320 and 330 may be adjusted to adjust the size of an amorphous layer and according to the type of dopant species. In some embodiments the ions 320 that are implanted into fin structure 304 may constitute a dose fraction of one third to one half the total dopant ion dose of ions 320 and 330. For example, ions 320 may constitute 4E14/cm² As ion dose, while ions 330 constitute a 6E14/cm² As ion dose, which thereby introduces a total ion dose of dopant species equal to 1E15/cm² into fin structure 304.

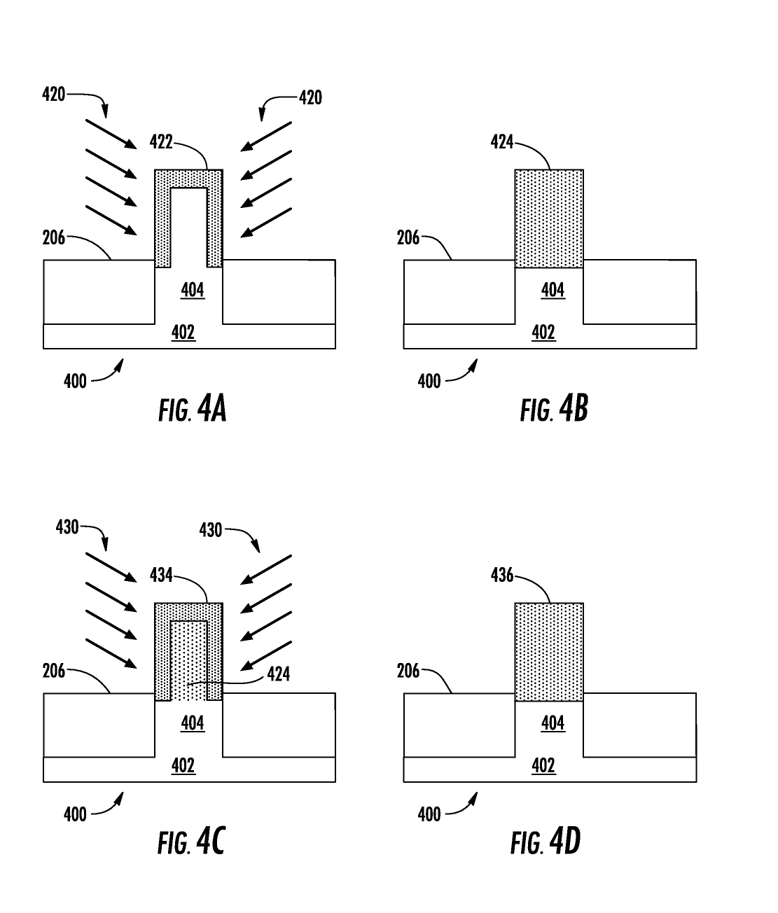

FIGS. 4A-4D depict various operations involved in an implantation process consistent with additional embodiments of the disclosure. In FIG. 4A a substrate 400 includes a semiconductor base 402 and fin structure 404, which may be as described above with respect to their counterparts semiconductor base 202 and fin structure 204. In the scenario depicted in FIGS. 4A-4D dopant implantation and annealing is conducted in an iterative fashion at an implant temperature designed so as not to generate defects that persist or evolve after post-implantation annealing. This may involve implanting a first dose of dopant ions followed by a first post implantation annealing, implanting a second dose of dopant ions followed by a second post implantation annealing, and so forth.

Turning now to FIG. 4A, ions 420 are dopant ions and may be implanted into the fin structure 404 similarly to the manner described with respect to FIG. 2A above. Notably, co-implantation of non-dopant atoms may also be performed in conjunction with the implantation of ions 420. Such non-dopant ions may include carbon, nitrogen, and fluorine, for example. In some examples, an implant temperature may be 250° C.-350° C., which temperature results in the formation of an amorphous layer 422.

Subsequently, as illustrated in FIG. 4B, the substrate 400 may be subjected to a post-implantation anneal as detailed above, resulting in the fin structure 404 having a doped region 424 that is monocrystalline and without visible defects. In accordance with various embodiments the implant dose of ions 420 may be limited such that the amorphous layer 422 is completely recrystallized into a monocrystalline region without polycrystalline regions or other defects. For example, it may be determined that a maximum dose of 3E14/cm² As ions may be implanted at 300° C. implant temperature into a particular fin structure without generating polycrystalline material or other defects after a post-implant anneal. Accordingly, the dose of ions 420 may be limited to 3E14/cm² As or less. Moreover, in order to introduce a total desired dose of ions into the fin structure 404 one or more additional implants may be performed, followed by a respective one or more additional anneals. This is illustrated in FIGS. 4C to 4D.

Turning now to FIG. 4C, there is shown an implant that is performed subsequently to the anneal whose results are depicted in FIG. 4B. In this example, ions 430 are implanted into the fin structure 404. The ions 430 are additional dopant ions and are used to introduce additional dopants into the fin structure 404. In some embodiments, an implant temperature may be 250° C.-350° C., which temperature results in the formation of an amorphous layer 434. In various embodiments the dose of ions 430 may be determined according to the previous dose implanted in a prior implant, as well as according to the target total ion dose to be implanted into the fin structure 404. Thus, following the aforementioned example in which a dose of 3E14/cm² As is implanted using ions 420, it may be desired to implant a total dose of 5E14/cm² As to achieve a desired dopant concentration. Accordingly, the dose of ions 430 may be set at 2E14/cm² As. Subsequently, as illustrated in FIG. 4D, a second post-implant anneal may be conducted, resulting in the fin structure 404, which now comprises a doped region 436 that is monocrystalline, without visible defects, and possessing the desired concentration of active dopants.

In various embodiments multiple implant/anneal cycles of dopant ions may be performed until a target ion dose is reached. More broadly, the exact implant temperature and ion dose may be chosen so that an amorphous layer is generated by the dopant ions and after each post-implant anneal is performed the amorphous layer is completely recrystallized into a monocrystalline region. Moreover the implant temperature of dopant ions may also be chosen so as not to generate defects that result in the presence of crystalline defects such as extended loops after annealing.

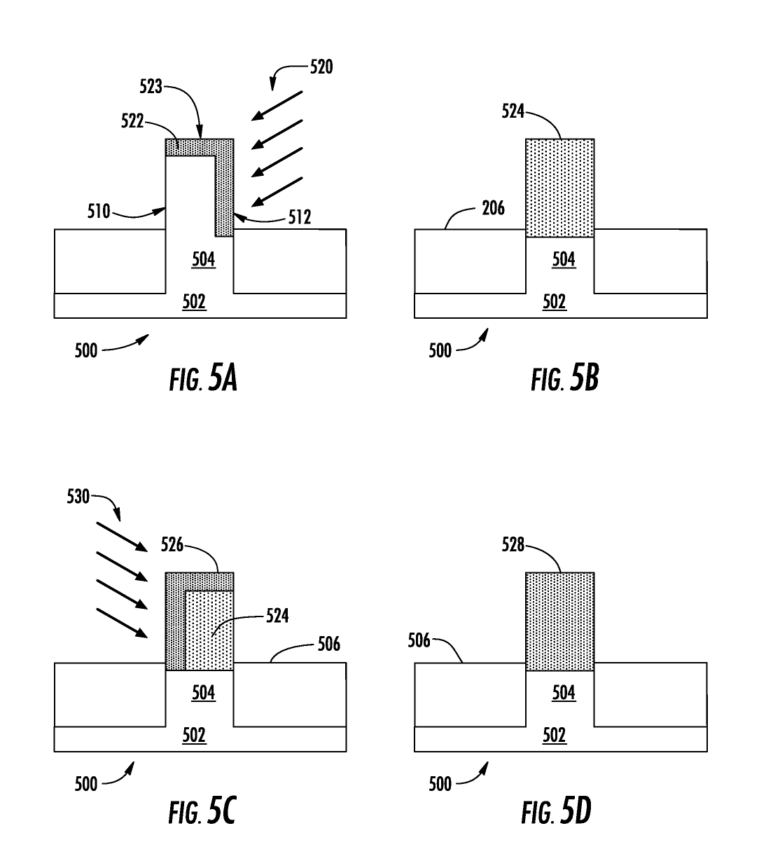

FIGS. 5A-5D depict additional operations involved in an implantation process consistent with still other embodiments of the disclosure. In FIG. 5A a substrate 500 includes a semiconductor base 502 and fin structure 504, which may be as described above with respect to their counterparts semiconductor base 202 and fin structure 204. In the scenario depicted in FIGS. 5A-5D dopant implantation and annealing of a sidewall 510 is conducted separately from dopant implantation and annealing of a sidewall 512.

Turning now to FIG. 5A, ions 520 are dopant ions and may be implanted into the fin structure 504 through the sidewall 512, as illustrated. An implant layer 522 is formed which may extend over the top of 523 of the fin structure 504. In various embodiments the implant temperature is 350° C. or below, which may render at least a portion of the implant layer 522 amorphous. A similar implant may be performed to implant the sidewall 510 as discussed below with respect to FIG. 5C. Because dopant ions are to be implanted separately in two different implants, the dose of ions 520 may be half a total desired dopant dose to be implanted into the fin structure 504.

In a subsequent operation the substrate 500 is subjected to a post implant anneal, which recrystallizes the amorphous portions of the implant layer 522. In FIG. 5B there is shown the resultant structure, fin structure 504, which includes a doped fin portion 524 that is monocrystalline and free of defects.

In order to increase the dopant level in the fin structure 504 a further implant is performed as shown in FIG. 5C. In this case, ions 530 are directed through a sidewall 510 of the fin structure 504, forming an implant layer 526. The conditions of implanting of ions 530 may, but need not, be the same as those for implanting ions 520 in some embodiments, including dopant species, ion dose, ion energy and implant temperature. A second post implant anneal may be performed subsequently, resulting in the doped region 528, which may be monocrystalline and free of defects. Because the total dopant dose is implanted in two separate implants into two different sidewalls, sidewalls 510, 512, in which annealing is performed between successive implants, the monocrystalline structure of the fin structure 504 may be more easily preserved than in cases in which the total dopant dose is introduced in one implant.

Although FIGS. have illustrated embodiments of implanting into thin fin structures, in other embodiments the aforementioned implantation and annealing processes may be performed using planar substrates in which a thin semiconductor layer is implanted with dopants without generating residual defects or polycrystalline semiconductor regions after post-implant annealing. For example, a pre-amorphizing implant may be performed into a thin SOI layer where the thickness of the semiconductor layer is 3 nm or less. This may be followed by a dopant implant at 450° C., for example.

In summary, the approaches disclosed in the present embodiments for dopant implantation into thin or narrow monocrystalline semiconductor structures entail two or more implants in which at least one implant introduces an amorphous layer. This layer may serve as defect sinks during post-implant annealing for any defects created, for example, during implants to introduce dopants into the semiconductor structure. The thickness of the amorphous layer and other damage is tailored so that the amorphous layer and other damage may be completely recrystallized into a monocrystalline microstructure consistent with the rest of the original semiconductor structure. This may be accomplished by choosing proper implant temperature and ion dose to limit the amorphous layer thickness. The present embodiments thus achieve a balance between preserving a thin or narrow monocrystalline portion of a semiconductor structure after implant to serve as a template for recrystallizing amorphous regions generated by an implant, while preserving enough of an amorphous layer to act as a defect sink for defects that may be generated within a monocrystalline semiconductor region during implantation. Without the amorphous layer, defects such as defect loops may be formed during post implant anneal resulting in inferior device properties.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Thus, the claims set forth below should be construed in view of the full breadth and spirit of the present disclosure as described herein.

What is claimed is:

1. A method to process a semiconductor device, comprising:
performing a first ion implant comprising first ions into a thin crystalline semiconductor structure, the first ion implant amorphizing a first region of the thin crystalline semiconductor structure;
performing a second ion implant comprising dopant ions of a dopant species into at least the first region of the thin crystalline semiconductor structure; and
performing at least one anneal of the semiconductor device after the first implant, wherein after the first and second implant and the at least one anneal, the thin crystalline semiconductor structure forms a mono-crystalline region without defects.

2. The method of claim 1, wherein the first ions comprise a non-dopant ions that do not act as dopant for the semiconductor device.

3. The method of claim 1, wherein an implant temperature of the second implant is 400° C. or greater.

4. The method of claim 1, wherein the first ions are Ge or Xe, or both, and wherein the dopant ions comprise arsenic species.

5. The method of claim 1, wherein the first ions comprise an ion energy less than 5 keV.

6. The method of claim 1, wherein the thin crystalline semiconductor structure comprises a fin structure than extends vertically from a substrate plane of the semiconductor device having a fin thickness less than 50 nm in a direction parallel to the substrate plane.

7. The method of claim 1, wherein the thin crystalline semiconductor structure comprises a semiconductor-on-insulator layer having a layer thickness of less than 50 nm.

8. The method of claim 1 wherein the second implant comprises an ion dose of 5E14/cm² to 2E15/cm² as ions.

9. The method of claim 1, wherein an anneal temperature of the anneal is greater than 800° C.

10. The method of claim 1, wherein the first ions comprise dopant ions, the first implant comprises an implant temperature of 300° C. or less, and wherein the second implant comprises an implant temperature of 400° C. or greater.

11. The method of claim 10, wherein the first ions and second ions comprise a total dopant ion dose, wherein the first ions comprise a dose fraction of one third to one half the total dopant ion dose.

12. The method of claim 1, wherein the first implant comprises implanting a first dose of dopant ions at an implant temperature between 250° C. to 350° C., and wherein the anneal is a first anneal and is performed before the second implant, and wherein the second implant comprises implanting a second dose of the dopant ions at an implant temperature between 250° C. to 350° C., the method further comprising performing a second anneal after the second implant.

13. The method of claim 6, wherein the first implant comprises implanting a first dose of dopant ions into a first sidewall of the fin structure, and wherein the anneal is a first anneal and is performed before the second implant, and wherein the second implant comprises implanting a second dose of the dopant ions into a second sidewall of the fin structure opposite the first sidewall, the method further comprising performing a second anneal after the second implant.

14. A method of forming a fin type field effect transistor (finFET), comprising:
providing a fin structure on a substrate extending perpendicularly to the substrate, the fin structure comprising a monocrystalline semiconductor having a fin thickness of less than 50 nm;
performing a first ion implant comprising first ions into the fin structure, the first ion implant amorphizing a first region of the fin structure;
performing a second ion implant comprising dopant ions of a dopant species into at least the first region of the fin structure at an implantation temperature above 300° C.; and
performing at least one anneal of the substrate after the first implant, wherein after the first and second implant and the at least one anneal, the fin structure forms a mono-crystalline region without defects.

15. The method of claim 14, wherein the first ions comprise a non-dopant ions that do not act as dopant for the substrate.

16. The method of claim 15, wherein the first ions are Ge or Xe, or both, and wherein the dopant ions comprise arsenic species.

17. The method of claim 14, wherein the implantation temperature is 400° C. or greater.
